(19) United States
(12) Patent Application Publication
(10) Pub. No.: US 2024/0030077 A1
(43) Pub. Date: Jan. 25, 2024

(54) PACKAGE AND METHOD OF FABRICATING THE SAME

(71) Applicant: SAMSUNG ELECTRONICS CO., LTD., Suwon-si (KR)

(72) Inventor: SANGHYEON JEONG, Suwon-si (KR)

(73) Assignee: SAMSUNG ELECTRONICS CO., LTD., Suwon-si (KR)

(21) Appl. No.: 18/121,158

(22) Filed: Mar. 14, 2023

(30) Foreign Application Priority Data
Jul. 21, 2022 (KR) 10-2022-0090430

(51) Int. Cl. H01L 23/16; H01L 25/065; H01L 25/00; H01L 21/48; H01L 23/13

(52) U.S. Cl. CPC H01L 23/16; H01L 25/0657; H01L 25/50; H01L 21/4846; H01L 23/13; H01L 2225/06517; H01L 2225/0652; H01L 2225/06548; H01L 2225/06572; H01L 24/16

(57) ABSTRACT

A package includes a lower substrate, a lower chip provided on the lower substrate, posts provided on an edge of the lower substrate and outside of the lower chip, an upper substrate provided on the posts and the lower chip, the upper substrate including a cavity formed on a bottom surface of the upper substrate, and a crack stiffener provided at an edge of the cavity, where the crack stiffener is configured to reduce formation of a crack in the upper substrate.

### CROSS-REFERENCE TO RELATED APPLICATION

This application is based on and claims priority under 35 U.S.C § 119 to Korean Patent Application No. 10-2022-0090430, filed on Jul. 21, 2022, in the Korean Intellectual Property Office, the disclosure of which is incorporated herein by reference in its entirety.

### BACKGROUND

The present disclosure relates to packages and methods of fabricating the same, and more particularly, to interposer package-on-packages and methods of fabricating the same.

A size of semiconductor chip becomes smaller with high integration of the semiconductor chip. However, the intervals between bumps on the semiconductor chip are fixed by an international standard of the Joint Electronic Device Engineering Council (JEDEC). Thus, it may be difficult to bond a desired number of the bumps to the semiconductor chip. In addition, as the size of the semiconductor chip becomes reduced, it becomes difficult to handle and test the semiconductor chip. Additionally, other issues, including acquiring diversified mount board in accordance with the size of the semiconductor chip, may occur. To address the problem mentioned issue, there have been suggested a fan-out panel-level package, an interposer package-on-package, and a package-on-package.

Furthermore, in accordance with the prevalence and high performance of various electronic products, the package process may require high difficulty techniques capable of satisfying diverse functions. An interposer package-on-package may include an interposer substrate on a lower substrate having a lower chip. The interposer substrate may have a thickness similar to that of the lower substrate. Based on various requests or standards, the interposer substrate may become thinner or include/produce a cavity, and the cavity may induce cracks in the interposer substrate.

### SUMMARY

One or more embodiments of the present disclosure provide a package capable of suppressing cracks of an upper substrate having a cavity.

Additional aspects will be set forth in part in the description which follows and, in part, will be apparent from the description, or may be learned by practice of the presented embodiments.

According to an aspect of an example embodiment, a package may include a lower substrate, a lower chip provided on the lower substrate, posts provided on an edge of the lower substrate and outside of the lower chip, an upper substrate provided on the posts and the lower chip, the upper substrate including a cavity formed on a bottom surface of the upper substrate, and a crack stiffener provided at an edge of the cavity, where the crack stiffener is configured to reduce formation of a crack in the upper substrate.

According to an aspect of an example embodiment, a package may include a lower substrate, a lower chip provided on the lower substrate, posts provided on the lower substrate and outside the lower chip, an upper substrate provided on the posts and the lower chip, the upper substrate including a cavity positioned over the lower chip, an upper chip provided on the upper substrate and positioned over the cavity, and a crack stiffener provided at an edge of the cavity below the upper chip, where the crack stiffener is configured to reduce formation of a crack in the upper substrate.

According to an aspect of an example embodiment, a method of fabricating a package may include forming posts on an edge of a lower substrate, mounting a lower chip on a center of the lower substrate and between the posts, forming a cavity on a bottom surface of an upper substrate, forming a crack stiffener at an edge of the cavity, and providing the upper substrate on the lower chip.

### BRIEF DESCRIPTION OF THE DRAWINGS

The above and other aspects, features, and advantages of certain example embodiments of the present disclosure will be more apparent from the following description taken in conjunction with the accompanying drawings, in which:

FIG. 1 is a diagram of an example of a package according to some example embodiments of the disclosure;

FIG. 2 is a cross-sectional view taken along line I-I′ of FIG. 1 according to example embodiments of the disclosure;

FIGS. 3A, 3B, and 3C are cross-sectional views of an example of a crack stiffener according to example embodiments of the disclosure;

FIG. 4 is a flowchart of a method of fabricating a package according to example embodiments of the disclosure;

FIGS. 5, 6, 7, 8 and 9 are cross-sectional views of a method of fabricating a package according to example embodiments of the disclosure; and

FIG. 10 is a cross-sectional view of an example of a package according to example embodiments of the disclosure.

### DETAILED DESCRIPTION

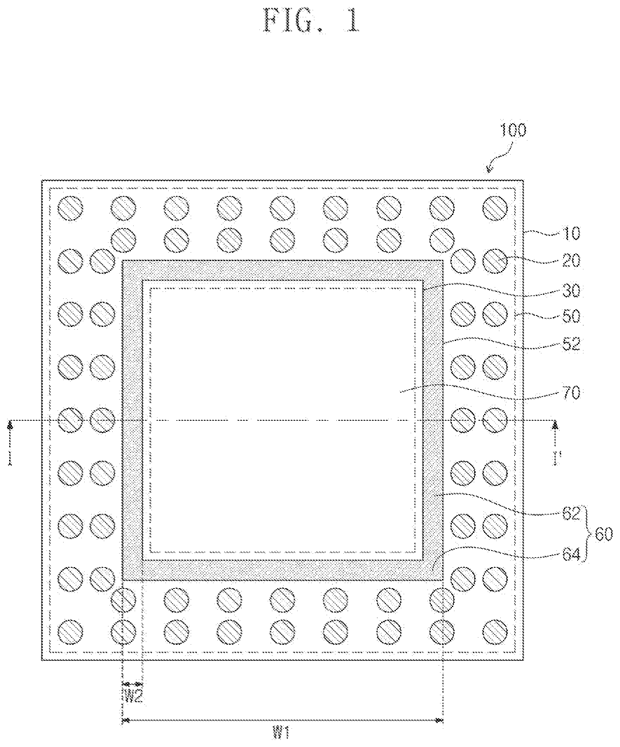

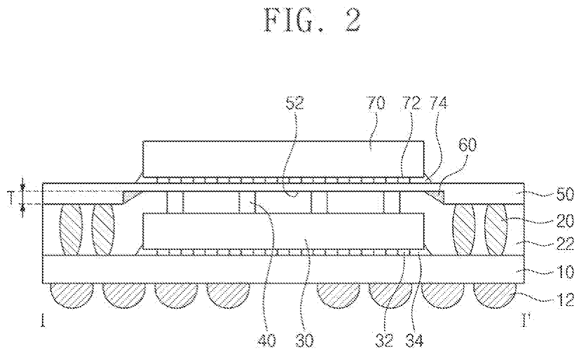

FIG. 1 is a diagram of an example of a package according to example embodiments of the disclosure. FIG. 2 is a cross-sectional view taken along line I-I′ of FIG. 1 according to example embodiments of the disclosure.

Referring to FIGS. 1 and 2, a package 100 of one or more embodiments of the disclosure may include an interposer package-on-package. According to an example embodiment, the package 100 of the disclosure may include a lower substrate 10, posts 20, a lower chip 30, spacers 40, an upper substrate 50, a crack stiffener 60, and an upper chip 70.

The lower substrate 10 may be provided below the posts 20 and the lower chip 30. The lower substrate 10 may have lower wiring lines that connect the lower chip 30 to the posts 20. For example, the lower substrate 10 may have a thickness ranging from about 80 μm to about 100 μm. The lower substrate 10 may include a redistribution layer or a redistribution substrate. Alternatively, the lower substrate 10 may include a printed circuit board, but embodiments of the disclosure are not limited thereto. According to example embodiments, the lower substrate 10 may have first lower bumps 12. The first lower bumps 12 may be provided below a bottom surface of the lower substrate 10. The first lower bumps 12 may include gold (Au), solder, copper (Cu), or silver (Ag), but embodiments of the disclosure are not limited thereto.

The posts 20 may be provided on an edge of the lower substrate 10. The posts 20 may be disposed outside the lower chip 30. The posts 20 may be connected through the lower substrate 10 to the lower chip 30. The posts 20 may be thicker than the lower chip 30. The posts 20 may be higher than the lower chip 30.

The lower chip 30 may be disposed on a center of the lower substrate 10. The lower chip 30 may be provided between the posts 20. The lower chip 30 may be connected through first upper bumps 32 to the lower substrate 10. The lower chip 30 may have a tetragonal shape when viewed in plan. The first upper bumps 32 may be provided in a first under-fill layer 34. The lower chip 30 may include an application processor chip. For example, the lower chip 30 may have a thickness of about 200 μm.

The spacers 40 may be provided between the lower chip 30 and the upper substrate 50. The spacers 40 may maintain a constant distance between the lower chip 30 and the upper substrate 50. For example, the spacers 40 may support the upper substrate 50. The spacers 40 may include a polymer block or a polymer ball, but embodiments of the disclosure are not limited thereto.

The upper substrate 50 may be provided on the lower substrate 10, the posts 20, the lower chip 30, and the spacers 40. The upper substrate 50 may include a printed circuit board. Alternatively, the upper substrate 50 may include a redistribution layer or a redistribution substrate, but embodiments of the disclosure are not limited thereto. The upper substrate 50 may have the same thickness as that of the lower substrate 10. For example, the upper substrate 50 may have a thickness ranging from about 80 μm to about 100 μm. A height between a top surface of the upper substrate 50 and the first lower bumps 12 may range from about 0.45 mm to about 0.5 mm. According to an example embodiment, the upper substrate 50 may have a cavity 52.

The cavity 52 may be provided on a bottom surface of the upper substrate 50 and at a center of the upper substrate 50. The cavity 52 may receive a top surface of the lower chip 30. In a plan view, the cavity 52 may have the same shape as that of the lower chip 30. The cavity 52 may have a square shape. For example, the cavity 52 may have a first width W1 ranging from about 5 mm to about 10 mm. The cavity 52 may have a depth ranging from about 10 μm to about 30 μm. The cavity 52 may have a tetragonal shape. The cavity 52 may have an area greater than that of the lower chip 30.

The crack stiffener 60 may be provided inside an edge of the cavity 52. The crack stiffener 60 may outwardly surround the spacers 40. The crack stiffener 60 may be provided on the bottom surface of the upper substrate 50. The crack stiffener 60 may be provided on an inner sidewall of the upper substrate 50 in the cavity 52. The crack stiffener 60 may include a resin, and may further include an epoxy.

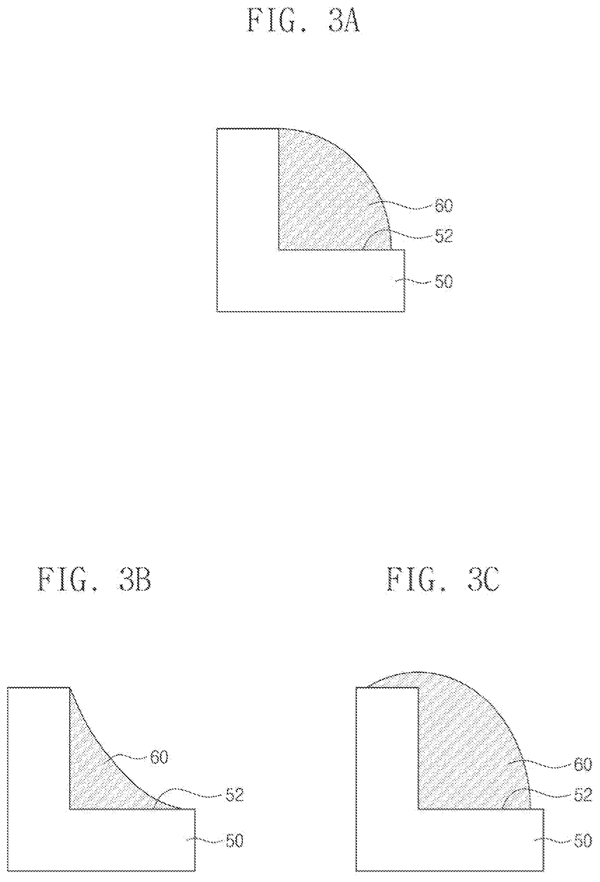

FIGS. 3A, 3B and 3C are cross-sectional views of an example of a crack stiffener depicted in FIG. 2 according to example embodiments of the disclosure.

Referring to FIGS. 3A to 3C, the crack stiffener 60 may have a partially triangular shape when viewed in vertical cross-section. The crack stiffener 60 may have a triangular shape with one side that is rounded. According to an example embodiment, the crack stiffener 60 may have one section having an arc shape when viewed in vertical cross-section. The crack stiffener 60 may have a thickness T the same as the depth of the cavity 52. For example, the crack stiffener 60 may have a thickness T ranging from about 10 μm to about 30 μm.

The crack stiffener 60 may have a tetragonal shape in a plan view. According to an example embodiment, the crack stiffener 60 may include linear stiffeners 62 and corner stiffeners 64. The linear stiffeners 62 may correspond to sides of the tetragonal shape. The linear stiffeners 62 may have a width W2 greater than the thickness T of the crack stiffener 60. For example, the second width W2 of the linear stiffeners 62 may be greater than the depth of the cavity 52. The second width W2 of the linear stiffeners 62 may be less than half the first width W1 of the cavity 52. For example, the second width W2 of the linear stiffeners 62 may range from about 10 μm to about 5 mm. The corner stiffeners 64 may correspond to vertices of the tetragonal shape. The linear stiffeners 62 and the corner stiffeners 64 may prevent damage or crack of the upper substrate 50 around the cavity 52. Therefore, the package 100 of the disclosure may use the crack stiffener 60 to minimize cracks of the upper substrate 50 in the vicinity of the cavity 52.

The upper chip 70 may be provided over the cavity 52 and on the upper substrate 50. The upper chip 70 may be connected to the lower chip 30 through the lower substrate 10, the posts 20, and the upper substrate 50. For example, the upper chip 70 may include a memory chip. The upper chip 70 may be connected through second upper bumps 72 to the upper substrate 50. The second upper bumps 72 may be provided in a second under-fill layer 74.

The following will describe a method of fabricating the package 100 configured as discussed above of the disclosure.

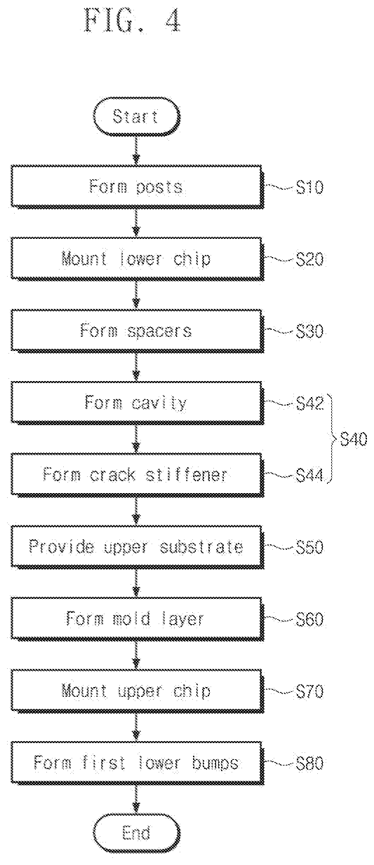

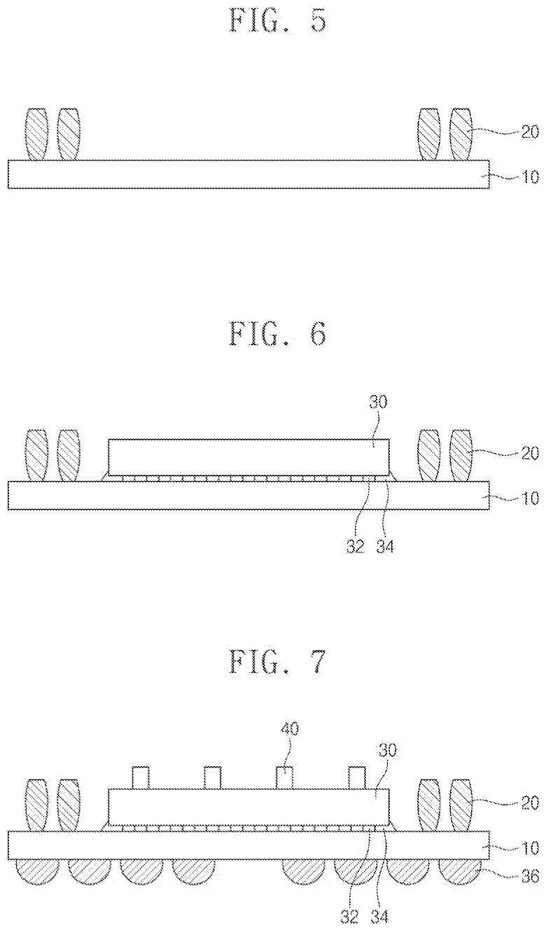

FIG. 4 is a flowchart of a method of fabricating a package according to example embodiments of the disclosure. FIGS. 5, 6, 7, 8 and 9 are cross-sectional views of a method of fabricating a package according to example embodiments of the disclosure.

Referring to FIGS. 4 and 5, in operation S10, posts 20 may be formed on a lower substrate 10. The posts 20 may be formed on an edge of the lower substrate 10. The posts 20 may be formed by a photolithography process and an electroplating process, but the disclosure are not limited thereto.

Referring to FIGS. 4 and 6, in operation S20, a lower chip 30 may be mounted on a center of the lower substrate 10 between the posts 210. The lower chip 30 may be mounted on the center of the lower substrate 10. The lower chip 30 may be connected through first upper bumps 32 to wiring lines of the lower substrate 10.

Referring to FIGS. 4 and 7, in operation S30, spacers 40 may be formed on the lower chip 30. The spacers 40 may include polymer blocks or polymer balls. The spacers 40 may be formed by a coating process, a film deposition process, or an etching process, but embodiments of the disclosure are not limited thereto.

Referring to FIGS. 4 and 8, in operation S40, an upper substrate 50 may be prepared on the lower substrate 10. The upper substrate 50 may include an interposer substrate. The upper substrate 50 may include a polymer substrate and wiring lines in the polymer substrate. The upper substrate 50 may be prepared through the following processes.

In operation S42 (of operation S40), a cavity 52 may be formed on a bottom surface of the upper substrate 50. For example, the cavity 52 may be formed by an etching process performed on the upper substrate 50. Alternatively, the cavity 52 may be formed by a molding process performed on the upper substrate 50, but the disclosure are not limited thereto.

In operation S44 (of operation S40), a crack stiffener 60 may be formed inside an edge of the cavity 52. For example, the crack stiffener 60 may include a resin, and may further include an epoxy. According to an example embodiment, the crack stiffener 60 may be formed by a printing method. For example, the crack stiffener 60 may be formed through an inkjet printing method or a screen printing method. Alternatively, the crack stiffener 60 may be formed by an under-fill process, a sol-gel method, a spin coating method, or a hot-melting method, but embodiments of the disclosure are not limited thereto. The crack stiffener 60 may minimize the occurrence of crack in the upper substrate 50.

In operation S50, an upper substrate 50 may be provided on the lower substrate 10, the posts 20, the lower chip 30, and the spacers 40. A top surface of the lower chip 30 may be provided in the cavity 52. The crack stiffener 60 may prevent the upper substrate 50 from crack or damage.

In operation S60, a mold layer 22 may be formed between the lower substrate 10 and the upper substrate 50. The mold layer 22 may fix the upper substrate 50 onto the lower substrate 10. The mold layer 22 may be formed by an under-fill process. Afterwards, the lower substrate 10, the mold layer 22, and the upper substrate 50 may be divided or cut by unit of the lower chip 30. In this step, the crack stiffener 60 may prevent the upper substrate 50 from crack or damage.

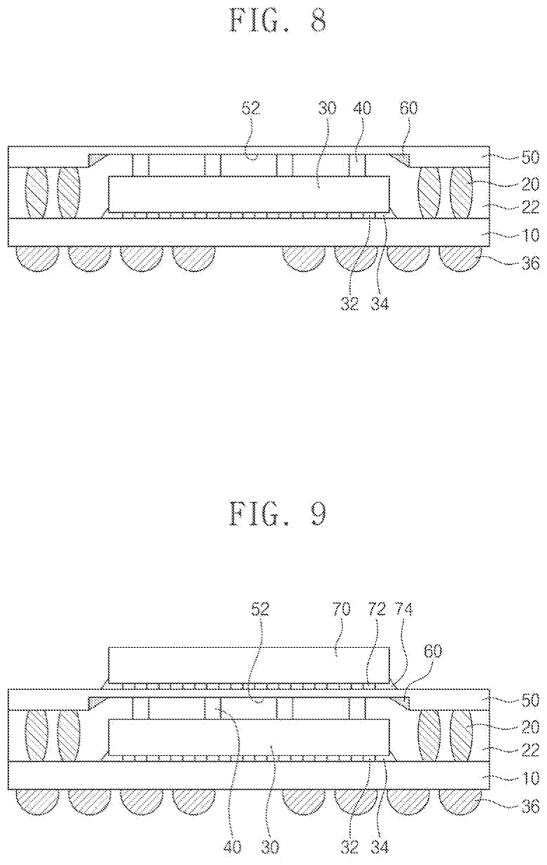

Referring to FIGS. 4 and 9, in operation S70, an upper chip 70 may be mounted on the upper substrate 50. The upper chip 70 may include a memory chip. The upper chip 70 may be connected through second upper bumps 72 to wiring lines of the upper substrate 50. The second upper bumps 72 may be provided in a second under-fill layer 74. The second under-fill layer 74 may fix the upper chip 70 onto the upper substrate 50.

Referring to FIGS. 2 and 4, in operation S80, first lower bumps 12 may be formed on a bottom surface of the lower substrate 10. The first lower bumps 12 may be electrically connected to the lower chip 30 and the upper chip 70. The first lower bumps 12 may connect the lower chip 30 and the upper chip 70 to an external substrate or an external device.

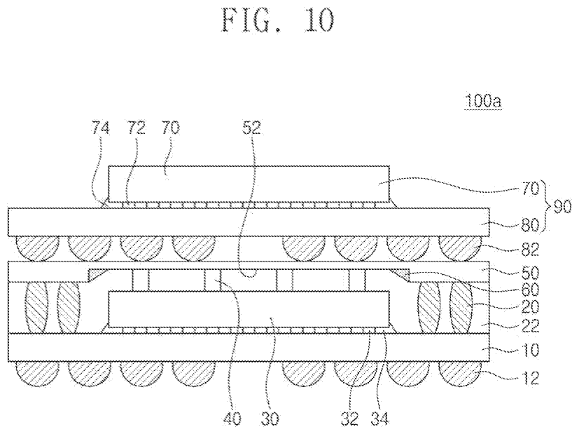

FIG. 10 is a cross-sectional view of an example of a package according to example embodiments of the disclosure.

Referring to FIG. 10, the package 100a of the disclosure may include a package-on-package. According to an example embodiment, the package 100 of the disclosure may include an upper package 90 on the upper substrate 50. The lower substrate 10, the posts 20, the lower chip 30, the spacers 40, the upper substrate 50, and the crack stiffener 60 may be configured similar to those of FIG. 2.

The upper package 90 may include an upper chip 70 and an upper package substrate 80. The upper package substrate 80 may be provided on the upper substrate 50. The upper package substrate 80 may have second lower bumps 82. The second lower bumps 82 may electrically connect the upper substrate 50 and the upper package substrate 80 to each other.

The upper chip 70 may be provided on the upper package substrate 80. The upper chip 70 may have second upper bumps 72. The second upper bumps 72 may be provided in a second under-fill layer 74. The second upper bumps 72 may connect the upper chip 70 to wiring lines in the upper package substrate 80. The second under-fill layer 74 may be provided between the upper chip 70 and the upper package substrate 80. The second under-fill layer 74 may fix the upper chip 70 onto the upper package substrate 80.

As discussed above, a package according to some example embodiments of the disclosure may be configured such that a crack stiffener inside an edge of a cavity is used to suppress cracks of an upper substrate. Example embodiments of the disclosure may minimize the occurrence of cracks by issuing a crack stiffener which may be formed on an inner sidewall in the cavity of the interposer substrate.

Each of the embodiments provided in the above description is not excluded from being associated with one or more features of another example or another embodiment also provided herein or not provided herein but consistent with the disclosure.

While the disclosure has been particularly shown and described with reference to example embodiments thereof, it will be understood that various changes in form and details may be made therein without departing from the spirit and scope of the following claims.

What is claimed is:

1. A package comprising:
a lower substrate;
a lower chip provided on the lower substrate;
posts provided on an edge of the lower substrate and outside of the lower chip;
an upper substrate provided on the posts and the lower chip, the upper substrate having a cavity formed on a bottom surface of the upper substrate; and
a crack stiffener provided at an edge of the cavity,
wherein the crack stiffener is configured to reduce formation of a crack in the upper substrate.

2. The package of claim 1, wherein the crack stiffener has a thickness that is the same as a depth of the cavity.

3. The package of claim 2, wherein the crack stiffener has a tetragonal shape.

4. The package of claim 3, wherein the crack stiffener comprises:
linear stiffeners corresponding to sides of the tetragonal shape; and
corner stiffeners provided at vertices of the tetragonal shape and connecting the linear stiffeners to each other.

5. The package of claim 4, wherein each of the linear stiffeners have a width that is greater than the depth of the cavity.

6. The package of claim 4, wherein each of the linear stiffeners have a width that is less than half of a width of the cavity.

7. The package of claim 4, wherein the linear stiffeners have a width of about 10 μm to about 5 mm.

8. The package of claim 1, wherein the crack stiffener comprises a resin.

9. The package of claim 8, wherein the crack stiffener further comprises an epoxy.

10. The package of claim 1, wherein the crack stiffener has a triangular sectional shape.

11. A package comprising:
a lower substrate;
a lower chip provided on the lower substrate;
posts provided on the lower substrate and outside the lower chip;
an upper substrate provided on the posts and the lower chip, the upper substrate having a cavity positioned over the lower chip;
an upper chip provided on the upper substrate and positioned over the cavity; and
a crack stiffener provided at an edge of the cavity below the upper chip,
wherein the crack stiffener is configured to reduce formation of a crack in the upper substrate.

12. The package of claim 11, wherein the lower chip comprises an application processor chip, and
wherein the upper chip comprises a memory chip.

13. The package of claim 11, wherein the crack stiffener comprises:
linear stiffeners; and
corner stiffeners provided between the linear stiffeners.

14. The package of claim 13, wherein each of the linear stiffeners have a width that is greater than a depth of the cavity and less than half of a width of the cavity.

15. The package of claim 11, wherein the crack stiffener has a triangular sectional shape.

16. A method of fabricating a package, the method comprising:
forming posts on an edge of a lower substrate;
mounting a lower chip on a center of the lower substrate and between the posts;
forming a cavity on a bottom surface of an upper substrate;
forming a crack stiffener at an edge of the cavity; and
providing the upper substrate on the lower chip.

17. The method of claim 16, wherein the crack stiffener has a width that is greater than a depth of the cavity and less than half of a width of the cavity.

18. The method of claim 16, further comprising:
forming spacers on the lower chip;
wherein the upper substrate is provided on the lower substrate, the lower chip, the posts, and the spacers.

19. The method of claim 18, wherein the crack stiffener is provided outside the spacers.

20. The method of claim 18, further comprising mounting an upper chip on the upper substrate and over the cavity.
